(19) United States
(12) Patent Application Publication
(10) Pub. No.: US 2025/0112199 A1
(43) Pub. Date: Apr. 3, 2025

(54) SELF-ALIGNMENT ASSISTED ASSEMBLY OF MULTI-LEVEL DIE COMPLEXES

(71) Applicant: Intel Corporation, Santa Clara, CA (US)

(72) Inventors: Thomas Sounart, Chandler, AZ (US); Feras Eid, Chandler, AZ (US); Adel Elsherbini, Chandler, AZ (US); Yi Shi, Chandler, AZ (US); Michael Baker, Gilbert, AZ (US); Kimin Jun, Portland, OR (US); Wenhao Li, Chandler, AZ (US)

(73) Assignee: Intel Corporation, Santa Clara, CA (US)

(21) Appl. No.: 18/374,520

(22) Filed: Sep. 28, 2023

(51) Int. Cl. H01L 23/00; H01L 25/065

(52) U.S. Cl. CPC H01L 24/80; H01L 24/08; H01L 25/0652; H01L 2224/08145; H01L 2224/08225; H01L 2224/80143; H01L 2224/80895; H01L 2224/80896

(57) ABSTRACT

Hybrid bonded multi-level die stacks, related apparatuses, systems, and methods of fabrication are disclosed. First-level integrated circuit (IC) dies and a base substrate each include hybrid bonding regions surrounded by hydrophobic structures. The hybrid bonding regions are brought together with a liquid droplet therebetween, and capillary forces cause the IC die to self-align. A hybrid bond is formed by evaporating the droplet followed by anneal. Hybrid bonding regions of second-level IC dies are similarly bonded to hybrid bonding regions on backsides of the first-level IC dies. This is repeated for any number of subsequent levels of IC dies. IC structures including the bonded IC dies and portions of the base substrate are segmented and assembled.

### BACKGROUND

The integrated circuit industry is continually striving to produce ever faster, smaller, and more efficient integrated circuit devices, packages, and systems for use in various electronic products. Current die stacks can be formed using solder to solder bump attachment techniques. For example, on two separate dies, solder bumps may be deposited on copper pillars. The solder bumps may then be brought into contact to join the dies, and underfill material may be formed between the solder bonds and copper pillars. Such processes disadvantageously necessitate a large distance between the bonded dies and limits the ability to scale to lower pitches.

Alternatively, hybrid bonds may be formed between corresponding metallic bond pads on the two dies, with the metallic bond pads interspersed among dielectric material (e.g., an oxide). Prior to bonding, the surface of each die may be controlled to promote bonding by providing a recess of the metallic bond pads relative to the dielectric material, having the dielectric material be planar and relatively smooth, and others. The dies, having mirror image bond pads, are then brought together such that corresponding metallic bond pads and corresponding dielectric material surfaces of the two dies interface with one another. At room temperature, the dielectric materials adhere sufficiently to one another (due to Van der Waals forces) to maintain a bond. A high temperature anneal is then performed to bond the corresponding metallic bond pads, and to improve the dielectric material bond. Such processes reduce the distance between the bonded dies, reduce pitches between the metal bonds, and offer other advantages. For example, solder bump techniques may be limited to pitches of about 30 μm while hybrid bonding can attain less than 10 μm and even less than 1 μm pitches.

However, difficulties in forming 3D die stacks using hybrid bonding techniques persist. It is with respect to these and other considerations that the present improvements have been needed. Such improvements may become critical as the desire to provide improved integrated circuit devices, packages, and systems becomes more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 provides a flow diagram illustrating an example process for fabricating IC structures inclusive of multi-level 3D die stacks with multiple levels bonded by hybrid bonding regions within containment features;

FIGS. 2, 3, 4A, 4B, 4C, 4D, and 4E are illustrations of cross-sectional side views of integrated circuit (IC) structures being prepared for self-alignment bonding;

FIG. 4F illustrates a top-down view of the IC structure of FIG. 4E showing bonding regions defined by a hydrophobic pattern;

FIGS. 5, 6, 7, 8, 9, 10, 11, 12, 13A, 13B, 14, 15, and 16 are illustrations of cross-sectional side views of IC structures during self-alignment bonding and hybrid bonding;

FIG. 17 is an illustration of a cross-sectional side view of an assembly structure similar to the IC structure of FIG. 12 after packaging and deployment of heat removal solutions;

FIG. 18 illustrates exemplary systems deploying a multi-level 3D die stack with multiple levels bonded by hybrid bonding regions within containment features; and

FIG. 19 is a functional block diagram of an electronic computing device, all arranged in accordance with at least some implementations of the present disclosure.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direction contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Integrated circuit structures, 3D die stack structures, devices, apparatuses, systems, and methods are described herein related to multi-level 3D die stacks interconnected by hybrid bonding regions contained within containment features.

As described above, hybrid bonding techniques offer advantages in the assembly of 3D die stacks. As used herein, the term multi-level 3D die stack indicates a stack of devices or structures having at least partially vertically aligned layers such that each layer or level of the 3D die stack may employ one or more IC dies each. The term layer or level of a 3D die stack indicates a horizontal portion of the 3D die stack that includes only one depth of device within the horizontal portion (e.g., each layer or level may have any number of IC dies in the horizontal plane). The term multi-level 3D die stack indicates a die stack having multiple levels such as two or more levels over a base substrate. The term IC die includes any monolithic integrated device that provides electrical, compute, memory, or similar functionality. IC dies include chiplets, chiplet dies, memory dies, processor dies, routing dies, and so on. Herein, the terms chiplet and IC die are used interchangeably. An IC die may be passive such that it only includes electrical routing, or it may be active such that it includes electrical devices such as transistors, capacitors, etc. The term base substrate, base wafer, or base die indicates a substrate having active or passive electrical features. In contrast, the term structural substrate, structural wafer, or structural die indicates a substrate absent any active or passive electrical features. For example, a structural substrate may be a monolithic material such as silicon, or other base material that provides structural support and heat removal.

In the context of hybrid bonding of IC dies, faster throughput may be attained during die-to-wafer hybrid bonding (D2 W HB) using self-alignment assisted assembly (SA3). In SA3 process flows, a liquid droplet is dispensed on the bonding area on either the top chiplet die or the base wafer to be bonded. A bonder is then used to pick and place the chiplet die onto the base wafer at coarse alignment (e.g., ˜25-50 um), such that the water droplet is sandwiched in the bonding area between the chiplet and the base wafer. Capillary forces cause the chiplet to self-align to its desired bonding location on the wafer with high positional accuracy (e.g., <200 nm) due to containment features (e.g., SA3 features) designed into the chiplet die and base wafer that confine the droplet to the bonding area with high precision. Such containment features may be characterized as alignment features, SA3 features, or the like. The liquid then evaporates, leaving the chiplet bonded to the base wafer at room temperature due to attractive surface forces (e.g., Van der Waals forces) between the dielectric regions on the chiplet and base wafer. An annealing step is then carried out to form and/or strengthen bonds between the metal pads (e.g., copper pads) dispersed between the dielectric regions, forming electrical interconnects between the chiplet and base wafer. The annealing step may also strengthen the bond between the dielectric regions.

Some current product architectures require stacking dies in two or more layers to form multi-level die complexes. It is advantageous to stack hybrid bonded die in the multi-level die complexes with hybrid bond interconnects between the multiple layers of the multi-level 3D stacks. Notably, assembly speed becomes even more important in such multi-level 3D stacks as the number of levels and therefore number of die transfers increases. Current die-to-wafer hybrid boding using accurate pick and place does not meet the required throughput in forming the multi-level 3D stacks. The techniques and structures discussed herein address these challenges by implementing containment features (e.g., SA3 features) at multiple levels in the assembly of the multi-level die complexes using die-to-wafer bonding, for example, at each level of the multi-level die complex. The containment features (e.g., SA3 features) enable fast throughput assembly of multi-level die complexes using die-to-wafer hybrid bonding, as discussed further herein. In some embodiments, the first level chiplet dies (e.g., those directly above a base substrate) have through vias (e.g., through silicon vias, TSVs) for backside connections such that the first level chiplet dies can be placed face-up or face-down on the base substrate (with the “face” side or surface being defined as having an active layer). After dielectric fill for the first level chiplet dies, a hybrid bonding layer is fabricated with containment features (e.g., SA3 features) for second level chiplet die bonding to any combination of first level chiplet dies with backside through vias or front side interconnects. The second level chiplet dies are then bonded using containment features (e.g., SA3 features) as discussed. This sequence of hybrid bonding using a droplet within containment features, forming a hybrid bonding layer over the bonded chiplets, containing hybrid bonding regions within containment features, hybrid bonding using a droplet within containment features, and so on can continue for any number of levels.

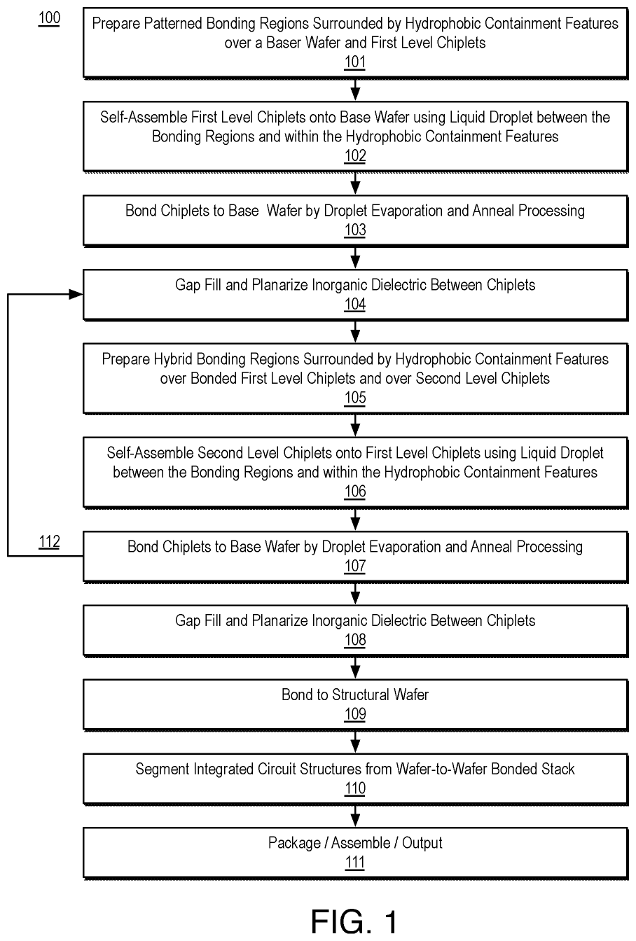

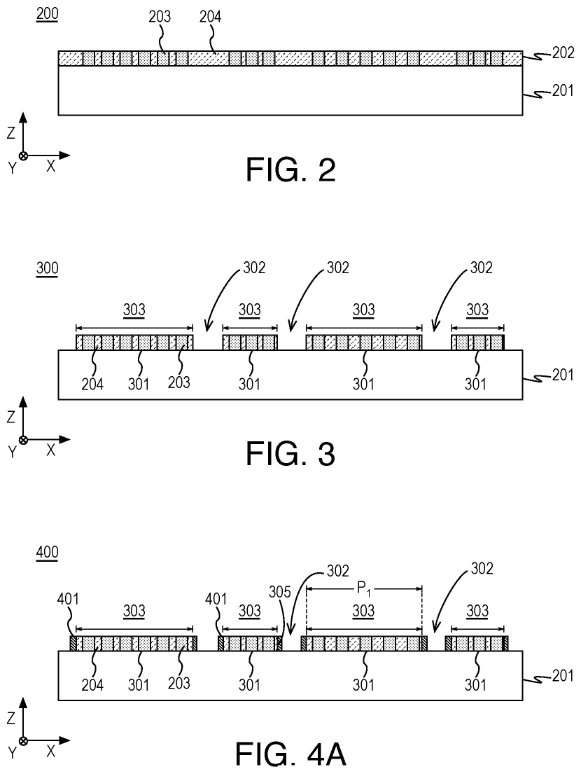

FIG. 1 provides a flow diagram illustrating an example process 100 for fabricating IC structures inclusive of multi-level 3D die stacks with multiple levels bonded by hybrid bonding regions within containment features, arranged in accordance with at least some implementations of the present disclosure. For example, process 100 may be implemented to fabricate IC structures 1200, 1500, 1600 or assembly structures including fabricate IC structures 1200, 1500, 1600 such as assembly structure 1700, or any other structure discussed herein. In the illustrated embodiment, process 100 includes one or more operations as illustrated by operations 101-112. However, embodiments herein may include additional operations, certain operations being omitted, or operations being performed out of the order provided. FIGS. 2, 3, 4A, 4B, 4C, 4D, 4E, and 5-17 illustrate structures and components as the methods of process 100 are practiced.

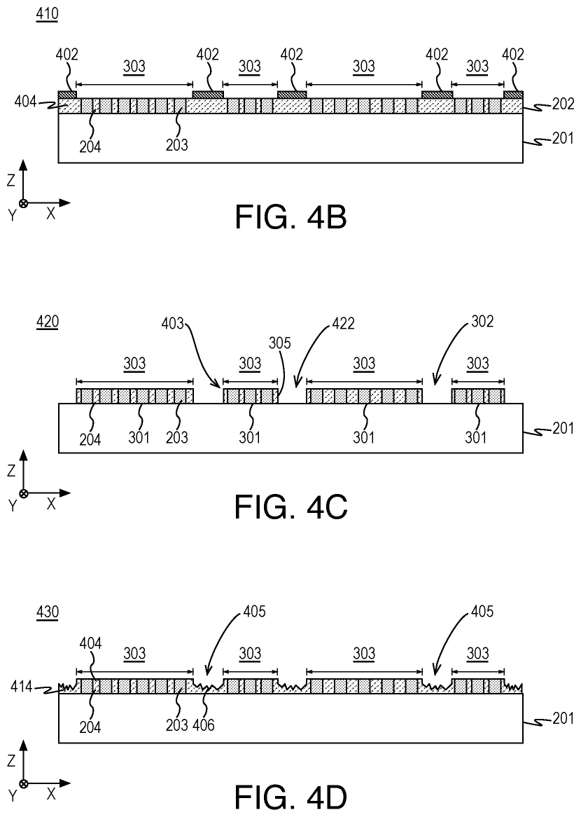

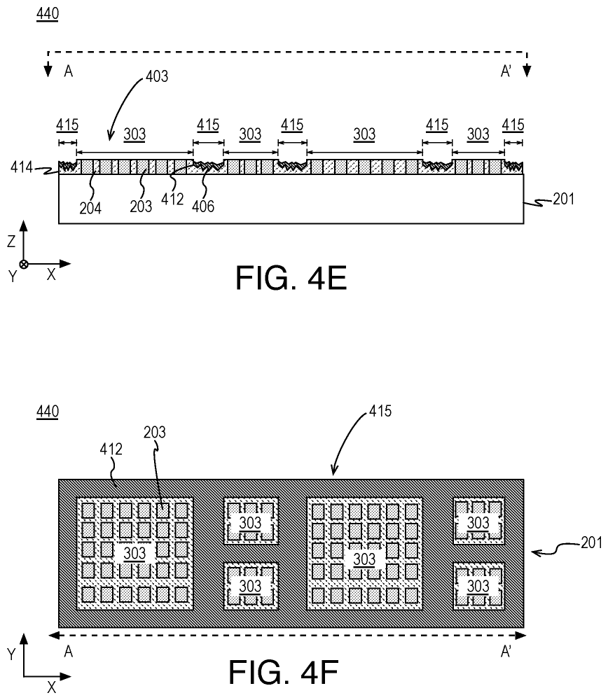

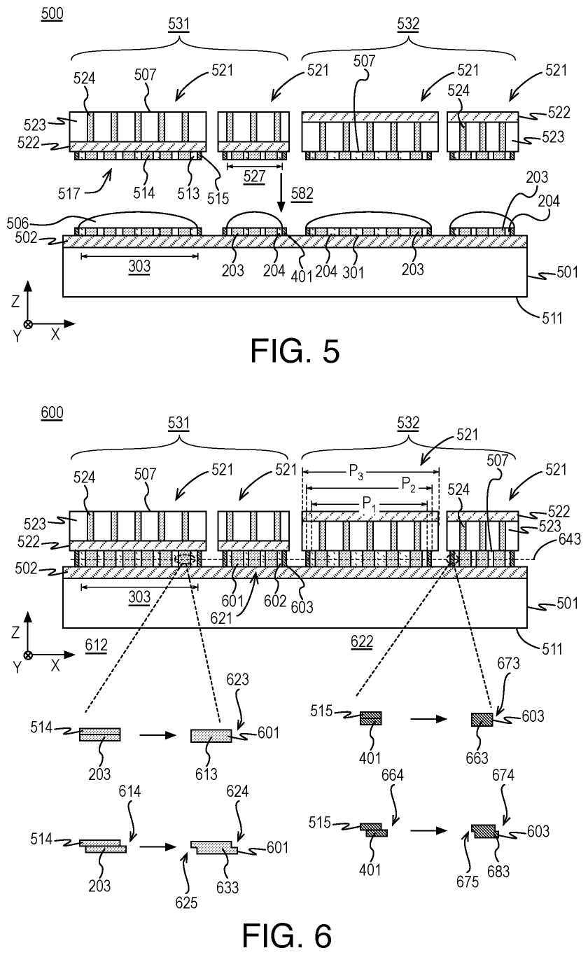

FIGS. 2, 3, 4A, 4B, 4C, 4D, and 4E are illustrations of cross-sectional side views of integrated circuit (IC) structures being prepared for self-alignment bonding, arranged in accordance with at least some implementations of the present disclosure. FIG. 4F illustrates a top-down view of the IC structure of FIG. 4E showing bonding regions defined by a hydrophobic pattern, arranged in accordance with at least some implementations of the present disclosure. FIGS. 5, 6, 7, 8, 9, 10, 11, 12, 13A, 13B, 14, 15, and 16 are illustrations of cross-sectional side views of IC structures during self-alignment bonding and hybrid bonding, arranged in accordance with at least some implementations of the present disclosure. FIG. 17 is an illustration of a cross-sectional side view of an assembly structure similar to the IC structure of FIG. 12 after packaging and deployment of heat removal solutions, arranged in accordance with at least some implementations of the present disclosure.

Process 100 begins at operation 101, where bonding areas surrounded by hydrophobic containment features are prepared over a base wafer and on IC dies or chiplets. In process 100, IC dies or chiplets are attached to a base wafer or substrate such that they may be directly attached to the base wafer or substrate or to a layer or level of IC dies or chiplets previously assembled. Such attachment techniques place the IC dies or chiplets onto the base substrate quickly and with gross alignment and then use a liquid droplet between a bonding region of the placed IC die or chiplet and a corresponding bonding region of the base substrate to provide fine alignment using capillary forces. Such self-alignment bonding techniques allow for high throughput as high accuracy, high duration pick and place alignment is not needed.

FIG. 2 is an illustration of a cross-sectional side view of an IC structure 200 being prepared for self-alignment bonding. As shown, IC structure 200 includes a substrate 201 and a hybrid bonding layer 202 formed on substrate 201. Substrate 201 may be a base wafer (as discussed further herein below) or a structural wafer or panel or the like on which IC dies or chiplets are being prepared for hybrid bonding. For example, substrate 201 may be a monolithic material, a crystalline material, or a composite material structural material or substrate 201 may be a base substrate including an interconnect layer, optional device layer, and routing through substrate 201 for connection to an outside package or board.

Hybrid bonding layer 202 includes metal bond pads 203 interspersed in an inorganic dielectric material 204. Inorganic dielectric material 204 may be any suitable material for forming a bond between hybrid bonding layer 202 and another hybrid bonding layer. As used herein, the term inorganic material indicates materials not having carbon as a foundational component or materials not having carbon-hydrogen bonds. In some embodiments, inorganic dielectric material 204 is silicon oxide. In some embodiments, inorganic dielectric material 204 is silicon nitride, silicon oxynitride, silicon carbonitride, or silicon carbide. In some embodiments, the out facing surface of hybrid bonding layer 202 may be planarized to a smooth finish for subsequent bonding. Metal bond pads 203 may be any suitable material for forming a bond between hybrid bonding layer 202 and another hybrid bonding layer and a suitable conductor for the application at hand. In some embodiments, metal bond pads 203 are copper but other metals may be used. In some embodiments, a bulk inorganic dielectric material is formed over substrate 201 and planarized. Metal bond pads 203 are then formed using any suitable technique or techniques such as single or dual damascene techniques.

FIG. 3 illustrates an IC structure 300 similar to IC structure 200 after formation of hydrophilic structures 301 for self-aligned bonding. As discussed, hydrophilic structures 301 include metal bond pads 203 interspersed in inorganic dielectric material 204, which may be silicon oxide, silicon nitride, silicon oxynitride, silicon carbonitride, or silicon carbide. Such materials are hydrophilic such that a liquid (e.g., water) will spread out on hydrophilic structures 301 as the liquid minimizes its surface energy. Patterned hydrophilic structures 301 therefore define hybrid bonding regions 303, which will be bonded to corresponding hybrid bonding regions to build multi-level 3D die stacks, as discussed further herein below.

Hydrophilic structures 301 and openings or trenches 302 may be formed from hybrid bonding layer 202 using any suitable technique or techniques such as patterning a resist layer on or over hybrid bonding layer 202, etching the exposed portions of hybrid bonding layer 202 (e.g., via dry etch), and removing the resist layer. In some embodiments, the pattern of hydrophilic structures 301, as defined by hybrid bonding regions 303, matches a desired layout of chiplets or IC dies on substrate 201.

FIG. 4A illustrates an IC structure 400 similar to IC structure 300 after formation of hydrophobic structures 401 adjacent hydrophilic structures 301. Hydrophobic structures 401 may be formed on sidewalls 305 of hydrophilic structures 301using any suitable technique or techniques. In some embodiments, a conformal hydrophobic material layer is formed on exposed surfaces of hydrophilic structures 301 and substrate 201 using, for example, spin coating or conformal vapor deposition. The conformal hydrophobic material layer is then removed from the lateral or horizontal surfaces while the conformal hydrophobic material layer remains on sidewalls 305 via an anisotropic etch such as a dry etch.

Hydrophobic structures 401, which may be characterized as hydrophobic spacers, hydrophobic materials, or the like may include any suitable hydrophobic material (e.g., material that causes a liquid water droplet to have a contact angle of greater than 90°). In some embodiments, hydrophobic structures 401 are chemical coatings or hydrophobic materials that create a hydrophobic boundary with a large contact angle (e.g., >90°) around hybrid bonding regions 303. In some embodiments, the hydrophobic material of hydrophobic structures 401 is or includes a self-assembled monolayer (SAM) material such as an alkyl or fluoroalkyl silane (e.g., ODS, FDTS), a thiol (e.g., hexadecane thiol), a phosphonic acid (e.g., octadecyl or perfluorooctane phosphonic acid), or an alkanoic acid (e.g., heptadecanoic acid). However, non-SAM based materials or films may be used. In some embodiments, the hydrophobic material of hydrophobic structures 401 is or includes a thin polymer film such as a siloxane (e.g., PDMS and derivatives, HMDSO), a silazane (HMDS), a polyolefin (e.g., PP), or a fluorinated polymer (e.g., PTFE, PFPE, PFDA, C4F8 plasma polymerized films, etc.). Other hydrophobic materials may be used.

As discussed, hydrophobic structures 401 will contain a liquid within hybrid bonding regions 303 while hydrophilic structures 301 allow the liquid to spread out in hybrid bonding regions 303. For example, hydrophilic structures 301 may be inorganic materials such as silicon oxide, silicon nitride, silicon oxynitride, silicon carbonitride, or silicon carbide. Such materials are hydrophilic such that a liquid (e.g., water) will spread out on hydrophilic structures 301 as the liquid minimizes its surface energy. Hydrophobic structures such as hydrophobic structures 401, in contrast, will contain the liquid. Hydrophilic materials or surfaces cause a liquid droplet to have a contact angle of less than 90° (e.g., water on silicon oxide has a contact angle of ˜10-20°) while a hydrophobic structure causes a contact angle of greater than 90° in the liquid droplet. As used herein, term hydrophobic structure is inclusive of both topological alterations to a material (e.g., alterations to an otherwise hydrophilic structure) and hydrophobic materials applied to a hydrophilic structure.

In the embodiment of FIG. 4A, hybrid bonding regions 303 are within hydrophobic structures 401 and trenches 302. Notably, trenches 302 are also hydrophobic structures, as discussed further with respect to FIG. 4C. The embodiment of FIG. 4A offers the advantages of multiple and diverse hydrophobic structures (e.g., both material based, and structure based hydrophobic structures) at the cost of increased fabrication complexity. FIGS. 4B-4E illustrate alternative hydrophilic structures and hydrophobic structures for the containment of a liquid within hybrid bonding regions 303.

FIG. 4B illustrates an IC structure 410 similar to IC structure 200 after formation of hydrophobic structures 402 to define hybrid bonding regions 303 as portions of hybrid bonding layer 202, which is also labeled as hydrophilic structure 404. Hydrophobic structures 402 may be formed using any suitable technique or techniques such as forming a conformal hydrophobic material layer on hybrid bonding layer 202, and subsequently patterning the conformal hydrophobic material layer by patterning a resist layer on or over the hydrophobic material layer, etching the exposed portions of the hydrophobic material layer, and removing the resist layer. For example, the pattern of hydrophobic structures 402 defines hybrid bonding regions 303.

Hydrophobic structures 402 may include any hydrophobic material discussed with respect to hydrophobic structures 401. For example, hydrophobic structures 402 may be or include a self-assembled monolayer material such as an alkyl or fluoroalkyl silane, a thiol, a phosphonic acid, or an alkanoic acid, or hydrophobic structures 402 may be or include a polymer film such as a siloxane, a silazane, a polyolefin, or a fluorinated polymer. Other hydrophobic materials may be used. As discussed, hydrophobic structures 402 will contain a liquid within hybrid bonding regions 303 while hydrophilic structure 404 allows the liquid to spread out within hybrid bonding regions 303. In the embodiment of FIG. 4B, hybrid bonding regions 303 are within hydrophobic structures 402 and on particular areas or regions of hydrophilic structure 404. Such structures offer the advantages of material based hydrophobic structures 402 with relative ease of manufacture.

FIG. 4C illustrates an IC structure 420 similar to IC structure 300 where trenches 302 are used as hydrophobic structures. As discussed, hydrophilic structures 301 cause a liquid (e.g., water) to spread out on hydrophilic structures 301 as the liquid minimizes its surface energy. Trenches 302, which may be characterized as hydrophobic structures 422, in contrast, will contain the liquid. In the context of FIG. 4C, the hydrophobic structure is trench 302 in hybrid bonding layer 202 such that sidewalls 305 and corners 403 are defined by trenches 302. Due to trenches 302, as a liquid droplet spread out, it interacts with corner 403, which alters the surface energy characteristics of the liquid droplet and, in turn, changes the effective contact angle to greater than 90°. As illustrated with respect to FIG. 4C, in some embodiments, trenches 302 extend to a top surface of substrate 201. Alternatively, a bottom of trenches 302 may include a portion of hybrid bonding layer 202. For example, any depth of trenches 302 that provides corner 403 may be deployed.

FIG. 4D illustrates an IC structure 430 similar to IC structure 200 after formation of hydrophobic structures 405 including roughened surfaces 406 for self-aligned bonding. Hydrophobic structures 405 may be formed using any suitable technique or techniques such as surface texturing techniques inclusive of laser surface roughening. Roughened surfaces 406 may have any suitable surface roughness relative to the surface of hydrophilic structure 404 in hybrid bonding regions 303. In some embodiments, the surface roughness (i.e., measured as the deviations in the direction of the normal vector of a real surface from its ideal form) of roughened surfaces 406 is not less than twice the surface roughness of the surface of hydrophilic structure 404 in hybrid bonding regions 303. For example, a ratio of the roughnesses may be defined as the surface roughness of roughened surfaces 406 divided by the surface roughness of the surface of hydrophilic structure 404 in hybrid bonding regions 303. In some embodiments, the ratio is not less than two. In some embodiments, the ratio is not less than five, ten, or twenty. In some embodiments, the ratio is not less than 100. Other surface roughness ratios may be used.

As discussed, hydrophobic structures 405 will contain a liquid within hybrid bonding regions 303 while modified layer 414 allows the liquid to spread out within hybrid bonding regions 303. In the embodiment of FIG. 4D, hybrid bonding regions 303 of modified layer 414 are contained between roughened surfaces 406.

FIG. 4E illustrates an IC structure 440 similar to IC structure 430 after formation of hydrophobic structures 412 to provide containment within hybrid bonding regions 303. Hydrophobic structures 412 may be formed using any suitable technique or techniques such as forming a conformal hydrophobic material layer on modified layer 414, and subsequently patterning the conformal hydrophobic material layer by patterning a resist layer on or over the hydrophobic material layer, etching the exposed portions of the hydrophobic material layer, and removing the resist layer. Hydrophobic structures 412 may include any hydrophobic material discussed herein such as a self-assembled monolayer material including an alkyl or fluoroalkyl silane, a thiol, a phosphonic acid, or an alkanoic acid, or a polymer film including a siloxane, a silazane, a polyolefin, or a fluorinated polymer. Other hydrophobic materials may be used. In accordance with some embodiments of the present disclosure, structures 412 may include a layer of material having an atomic composition of at least 10% carbon, a layer of material having an atomic composition of at least 10% fluorine, a layer of material having an atomic composition of at least 10% phosphorus, a layer of material having an atomic composition of at least 10% sulfur, and/or or a layer of material having an atomic composition of at least 10% silicon.

Hydrophobic structures 412 further aid, along with roughened surfaces 406, in the containment of a liquid within hybrid bonding regions 303 while hybrid bonding regions 303 allow the liquid to spread out. As shown in FIG. 4E, any of the previously discussed hydrophobic structures defines keep out regions or a hydrophobic pattern 415 that fully or nearly fully surrounds each of hybrid bonding regions 303 with hydrophobic structures.

FIG. 4F illustrates a top-down view of IC structure 440 showing hybrid bonding regions 303 defined by hydrophobic pattern 415. In the example of FIG. 4F, hydrophobic structures 412 and hydrophobic structures 405 provide containment within hybrid bonding regions 303 (with only hydrophobic structures 412 being visible in the top-down view). However, any of hydrophobic structures 401, 402, 422, 405 may provide the same hydrophobic pattern 415. As shown, hybrid bonding regions 303 may be the same or different sizes and hybrid bonding regions 303 define a chiplet or IC die layout on substrate 201, which underlies hydrophobic pattern 415 and hybrid bonding regions 303. In some embodiments, an IC die or chiplet is first gross aligned to each of hybrid bonding regions 303. This gross alignment may be performed by pick and place equipment and may be within, for example, 25-50 μm. A liquid droplet (e.g., water droplet) between each of hybrid bonding regions 303 and the corresponding IC die or chiplet then, via capillary forces, provides fine alignment (in a self-aligned manner) of the IC die or chiplet within each of hybrid bonding regions 303. This fine alignment may be to within, for example, 200 nm or less. Alternatively, chiplets may be diced from substrate 201 based on hydrophobic pattern 415 to provide IC dies or chiplets for bonding to a base substrate.

Returning to FIG. 1, process 100 continues at operation 102, where a first level of IC dies or chiplets are self-assembled onto a base wafer using a liquid droplet between bonding regions and within the hydrophobic containment features prepared at operation 101. In some embodiments, the water droplet is applied to a hydrophilic bonding region over a base substrate. In some embodiments, the water droplet is applied to a hydrophilic bonding region of the IC dies or chiplets. In either event, the IC die hydrophilic bonding region is placed on or over the hydrophilic bonding region of the base substrate (using gross alignment) and the interplay of the droplet, the hydrophilic bonding regions, and the hydrophobic containment features cause the IC die to self-align with high accuracy.

FIG. 5 is an illustration of a cross-sectional side view of an IC structure 500 during self-alignment bonding. As shown, IC structure 500 includes hydrophilic structures 301 on or over base substrate 501 and hydrophobic structures 401 adjacent hydrophilic structures 301 and also on or over base substrate 501. Although illustrated with respect to hydrophilic structures 301 and hydrophobic structures 401, any hydrophilic structures 301 and hydrophobic structures discussed herein may be deployed in the IC structures of FIGS. 5-17. Hydrophobic structures 401 and adjacent hydrophilic structures 301 may be formed over base substrate 501 using any suitable technique or techniques discussed above.

As shown, base substrate 501 includes an active layer 502. Active layer 502 (or an active surface) includes a device layer and/or an interconnect layer. For example, a device layer may include transistors, capacitors, or other IC devices. An interconnect layer may be over the device layer and may include metallization levels that interconnect the devices of the device layer and provide routing to outside devices. In some embodiments, base substrate 501 includes active devices in active layer 502 and routing from active layer 502 to a backside surface 511 of base substrate 501. In some embodiments, base substrate 501 includes routing from active layer 502 to backside surface 511, and is absent active devices. Base substrate 501 may include any suitable material or materials such as a semiconductor material such as monocrystalline silicon (Si), germanium (Ge), silicon germanium (SiGe), III-V materials (e.g., gallium arsenide (GaAs)), silicon carbide (SiC), sapphire (Al₂O₃), or any combination thereof. As discussed, a base substrate, base wafer, or base die indicates a substrate having active or passive electrical features. In some embodiments, a multi-level stack of IC dies is formed over base substrate 501 using die-to-wafer bonding and 3D die complexes are segmented from base substrate 501 such that each 3D die complex includes a portion of base substrate 501 and the pertinent attached chiplets over the segmented portion of base substrate 501.

Furthermore, each of IC dies 521 includes a substrate 523, an active layer 522, and through vias 524 extending between active layer 522 and a backside surface 507 of each of IC dies 521. Active layer 522 (or an active surface), similar to active layer 502, includes a device layer and/or an interconnect layer. For example, the device layer may include transistors, capacitors, or other IC devices. The interconnect layer may be over the device layer and may include metallization levels that interconnect the devices of the device layer and provide routing to outside devices. Substrate 523 may include any suitable material or materials such as a semiconductor material such as monocrystalline silicon (Si), germanium (Ge), silicon germanium (SiGe), III-V materials (e.g., gallium arsenide (GaAs)), silicon carbide (SiC), sapphire (Al₂O₃), or any combination thereof. Backside surface 507 is opposite active layer 522 and may be characterized as a non-active surface.

On or over each of IC dies 521, hydrophilic structures 517 (analogous to hydrophilic structures 301) and hydrophobic structures 515 (analogous to hydrophobic structures 401) are formed as discussed herein above to define hybrid bonding regions 527. For example, hydrophilic structures 517 include metal bond pads 514 and inorganic dielectric material 513, which may have any characteristics discussed with respect to metal bond pads 203 and inorganic dielectric material 204. Similarly, hydrophobic structures 515 may have any characteristics discussed with respect to hydrophobic structures 401 and, although illustrated with respect to hydrophobic structures 515 being similar to hydrophobic structures 401, any hydrophobic structures discussed herein may be deployed. Hydrophilic structures 517 and hydrophobic structures 515 may be formed over a wafer including one or more of IC dies 521 using the techniques discussed above, and IC dies 521 may be segmented (e.g., diced) from the wafer for pick and place onto hybrid bonding regions 303, for example. Notably, the structures discussed with respect to FIGS. 2, 3, and 4A-4F may be formed with respect to hydrophilic structures 517 and hydrophobic structures 515 without limitation.

The combination of hydrophilic structures/hydrophobic structures over base substrate 501 and the combination of hydrophilic structures/hydrophobic structures on IC dies 521 may be the same (as shown) or they may be different. Notably, the hydrophilic structures/hydrophobic structures illustrated with respect to FIG. 4B may only be compatible with other hydrophilic structures/hydrophobic structures (i.e., any but those of FIG. 4B) since hybrid bonding regions 303, 527 surrounded by hydrophobic structures of FIG. 4B would not be in contact if used on both base substrate 501 and any of IC dies 521.

As shown, liquid droplets 506 are placed on hybrid bonding regions 303 of hydrophilic structures 301 (or on bonding regions 527 of hydrophilic structures 517). Liquid droplets 506 may be any suitable liquid such as water of any suitable volume. Hybrid bonding regions 303 and hybrid bonding regions 527 are brought together using, for example, pick and place of IC dies 521. As shown, liquid droplets 506 spread out on hybrid bonding regions 303 (or hybrid bonding regions 527) and are contained by hydrophobic structures 401 (or hydrophobic structures 515). IC dies 521 are grossly and advantageously quickly aligned to hybrid bonding regions 303 and liquid droplets 506 by pick and place 582, confined by the self-alignment assisting features discussed herein, quickly fine align each of IC dies 521 to the corresponding bonding region 303.

IC dies 521 may be fabricated and attached such that they are in a face-down configuration 531 or a face-up configuration 532. In face-down configuration 531, active layer 502 and active layer 522 are adjacent one another and are directly connected by a hybrid bond therebetween, as discussed further below. Advantageously, through vias 524 (which may be characterized as through substrate vias or through silicon vias, TSVs), have backside connections on or over backside surface 507 such that routing from the hybrid bond and active layer 522 is provided to additional IC dies in the stack (e.g., extending in the z-dimension). In face-up configuration 532, active layer 522 is opposite substrate 523 with respect to active layer 522. In such contexts, through vias 524 again have backside connections on or over backside surface 507 such that routing from the hybrid bond may be provided to active layer 522, and then to additional IC dies in the stack (e.g., extending in the z-dimension).

Returning to FIG. 1, process 100 continues at operation 103, where the IC dies or chiplets are bonded to the base substrate or wafer by evaporating the liquid droplets and anneal processing. For example, the liquid droplet applied at operation 102 evaporates relatively quickly after alignment and the inorganic materials hold the IC dies or chiplets in place due to, for example, Van der Waals forces. A subsequent anneal operation may be performed to bond the IC dies or chiplets to the bonding regions of the structural wafer by melding metal bond pads and the inorganic materials therebetween.

FIG. 6 is an illustration of a cross-sectional side view of an IC structure 600 similar to IC structure 500 after liquid droplets 506 evaporate and after bonding to form composite metal structures 601 and a composite dielectric portion 602 between each of IC dies 521 and base substrate 501. Furthermore, hydrophobic structures 401, 515 may bond to form composite hydrophobic structures 603. In other contexts, no bonding between hydrophobic structures 401, 515 occurs. In some embodiments, the hydrophobic structures 401, 515 may partially or fully decompose and volatize during hybrid bond annealing. As shown, IC structure 600 includes base substrate 501 coupled to active layers 522 or backside surfaces 507 of each IC die 521, depending on whether each IC dies was in face-down configuration 531 or face-up configuration 532 during bonding.

As shown, the discussed hybrid bonding forms composite metal structures 601 and a composite dielectric portion 602 across a bonding plane 643. Thereby, a hybrid bond 621 between IC dies 521 and base substrate 501 is formed. Each hybrid bond 621 includes composite metal structures 601 and composite dielectric portion 602. Composite dielectric portion 602 may be characterized as an inorganic material, an inorganic bond layer, an inorganic bonding material, or the like. As shown, each hybrid bond 621 is surrounded by composite hydrophobic structures 603 or by the pertinent hydrophobic structures deployed in forming hybrid bond 621.

As shown in insert 612, in some embodiments, adjacent metal pads are annealed to form a composite metal structure 613 (one of composite metal structures 601) such that metal structure 613 has a substantially aligned sidewalls 623. However, in other embodiments, adjacent metal pads 203, 514 have a misalignment 614 during anneal and form a composite metal structure 633 such that metal structure 633 has a substantially misaligned sidewalls and therefore metal structure 633 includes a jut 624 and an overhang 625. For example, the sidewall of metal structure 633 may have substantially vertical sidewall portions and a substantially horizontal sidewall portion (e.g., at jut 624 and overhang 625).

Similarly, as shown in insert 622, in some embodiments, adjacent hydrophobic structures 401, 515 form a composite hydrophobic structure 663 (e.g., any of composite hydrophobic structures 603) that has substantially aligned sidewalls 673. However, in other embodiments, adjacent hydrophobic structures 401, 515 have a misalignment 664 during anneal and form a composite hydrophobic structure 683 (e.g., any of hydrophobic structures 603) that has a substantially misaligned sidewall 674 and therefore hydrophobic structure 683 includes a jut or overhang 675. For example, the sidewall of hydrophobic structure 683 may have substantially vertical sidewall portions and a substantially horizontal sidewall portion. In some embodiments, composite hydrophobic structure 603 extends from a surface of active layer 502 to active layer 522 or backside surface 507 or IC dies 521.

As discussed, each hybrid bond 621 is surrounded (entirely or mostly, i.e., >90%) by hydrophobic structures 603. In the context of FIG. 6, hydrophobic structures 603 are formed of hydrophobic structures 401, 505, though the materials of hydrophobic structures 401, 505 may not combine or meld. As shown in FIG. 6, hydrophobic structure 603 extends around a perimeter P1 of hybrid bond 621 (refer to FIG. 4F). As used herein, the term perimeter is used in its ordinary meaning to indicate an outer boundary of hydrophobic structure 603 in the x-y plane. For perimeters that are not taken in the same plane, such perimeters are projected into the same plane for determination of their dimensions. Furthermore, an outer perimeter P2 of hydrophobic structure 603 is fully within an outer perimeter P3 of IC die 521. It is noted that a single continuous hydrophobic structure 603 may surround hybrid bond 621 or multiple discontinuous hydrophobic structures 603 may surround hybrid bond 621.

Returning to FIG. 1, process 100 continues at operation 104, where a gap fill dielectric is formed between the first level IC dies and planarized to provide a top surface for second level IC die or chiplet attachment in the multi-level 3D die stacks. In some embodiments, the gap fill dielectric is an inorganic dielectric material such as silicon nitride, silicon oxynitride, silicon carbonitride, or silicon carbide. The gap fill dielectric may be formed using any suitable technique or techniques such as deposition techniques followed by planarization.

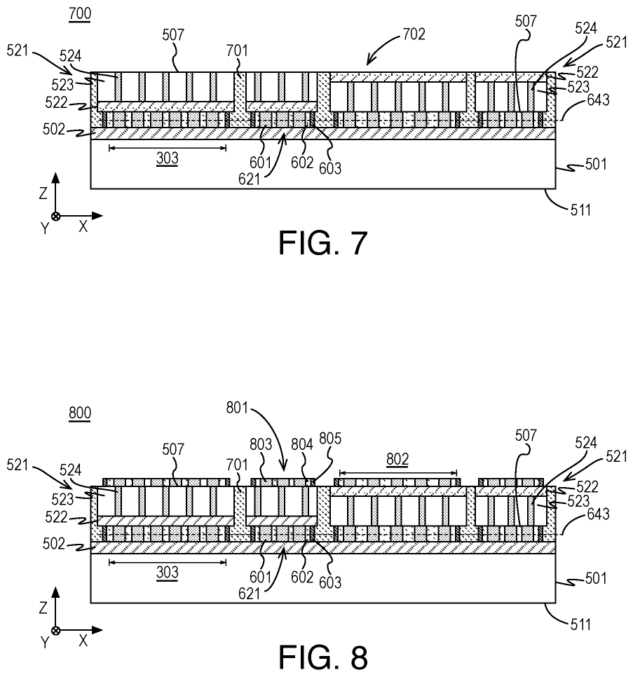

FIG. 7 is an illustration of a cross-sectional side view of IC structure 700 similar to IC structure 600 after forming inorganic dielectric 701 and a substantially planar surface 702. As shown, inorganic dielectric 701 may be deposited as a fill material using any suitable technique or techniques such as vapor deposition techniques. The fill material is then planarized using chemical mechanical polishing techniques, to form planar surface 702. Inorganic dielectric 701 may be any material suitable dielectric material such as silicon oxide, silicon nitride, silicon oxynitride, silicon carbonitride, silicon carbide, or combinations thereof (e.g., a layer of one of those materials covered by a second layer of another one of those materials). Although inorganic dielectric materials may be advantageous, organic dielectrics may be deployed. As discussed below, planar surface 702 provides a surface for a subsequent level of IC dies or chiplets in a multi-level 3D die stack.

Returning to FIG. 1, process 100 continues at operation 105, where hybrid bonding regions surrounded by hydrophobic containment features are formed in preparation for a subsequent level of IC dies or chiplets in the multi-level 3D die stack. The hybrid bonding regions and hydrophobic containment features may be formed using any suitable technique or techniques such as those discussed with respect to operation 101 and FIGS. 2, 3, and 4A-4F. In some embodiments, a bulk inorganic dielectric material is formed over the first level of IC dies or chiplets, and the inorganic dielectric material is then planarized. Metal bond pads may then be formed interspersed in the inorganic dielectric material using any suitable technique or techniques such as single or dual damascene techniques. The hydrophobic containment features may then be formed around hybrid bonding regions as discussed above. Such hybrid bonding regions surrounded by hydrophobic containment features are formed both over the base substrate (e.g., over the already attached first level IC dies or chiplets) and over IC dies or chiplets that are to be bonded thereto (e.g., over the to-be-attached second level IC dies or chiplets).

FIG. 8 illustrates an IC structure 800 similar to IC structure 700 after formation of hydrophilic structures 801 surrounded by hydrophobic structures 805, each for self-aligned bonding to base substrate 501. Hydrophilic structures 801 may have any characteristics discussed with respect to hydrophilic structures 301, and hydrophilic structures 801 include metal bond pads 803 interspersed in inorganic dielectric material 804, which may be silicon oxide, silicon nitride, silicon oxynitride, silicon carbonitride, or silicon carbide. Hydrophobic structures 805 may have any characteristics discussed herein above, and hydrophobic structures 805 define hybrid bonding regions 802.

Returning to FIG. 1, process 100 continues at operation 106, where a second level of IC dies or chiplets are self-assembled onto a base wafer using a liquid droplet between bonding regions and within the hydrophobic containment features prepared at operation 103. The water droplet may be applied to a hydrophilic bonding region of the base substrate or the IC die or chiplet being attached. As discussed, after gross alignment, the interplay of the droplet, the hydrophilic bonding regions, and the hydrophobic containment features cause the second level IC dies to self-align with high accuracy.

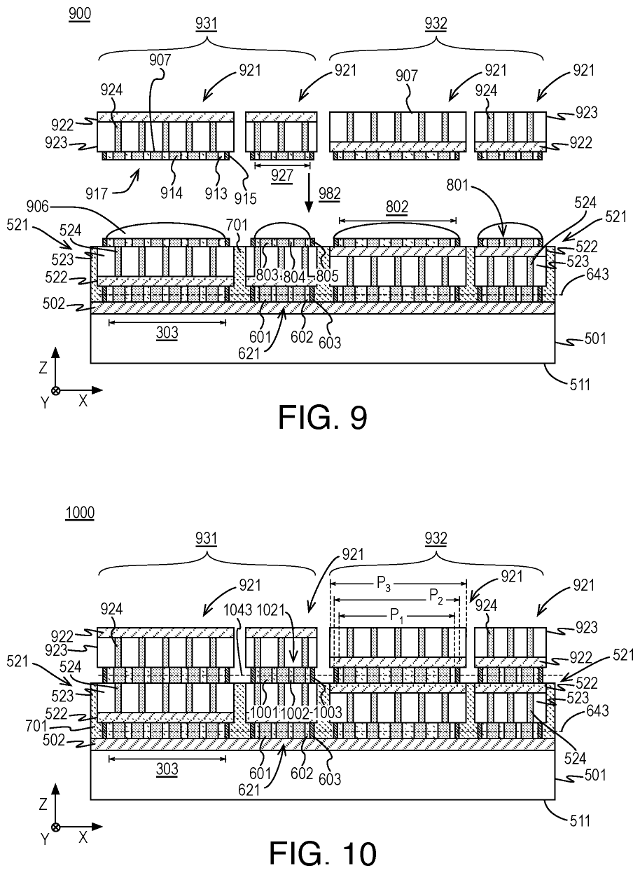

FIG. 9 is an illustration of a cross-sectional side view of an IC structure 900 similar to IC structure 800 during self-alignment bonding. As discussed, IC structure 900 includes hydrophilic structures 801 over base substrate 501 and hydrophobic structures 801 adjacent and surrounding hydrophilic structures 801. Furthermore, IC structure 900 includes a number of second-level IC dies 921 that each include a substrate 923, an active layer 922, and through vias 924 extending between active layer 922 and a backside surface 907 thereof. Active layer 922 may have any characteristics discussed with respect to active layer 522 and substrate 923 may have any characteristics discussed with respect to substrate 523.

On or over each of IC dies 921, hydrophilic structures 917 and hydrophobic structures 915 are formed to define hybrid bonding regions 927. Hydrophilic structures 917 include metal bond pads 914 interspersed in inorganic dielectric material 913, which may have any characteristics discussed with respect to other hybrid bonding regions herein. Any suitable combination of hydrophilic structures/hydrophobic structures may be deployed IC structure 900. As shown, liquid droplets 906 are placed on hybrid bonding regions 802 of hydrophilic structures 801 (or on bonding regions 927 of hydrophilic structures 917) and hybrid bonding regions 802 and hybrid bonding regions 927 are brought together using, for example, pick and place 982 of IC dies 921. Liquid droplets 906 spread out on hybrid bonding regions 802, 927 and are contained by hydrophobic structures 805, 915. As discussed, IC dies 921 are grossly and quickly aligned, and liquid droplets 506 quickly fine align each of IC dies 921.

IC dies 921 may be fabricated and attached such that they are in a face-down configuration 932 or a face-up configuration 931. In face-down configuration 932, active layers 522 and active layers 922 may be adjacent one another and maybe directly connected by a hybrid bond therebetween. Alternatively, in face-down configuration 932, active layer 922 may be adjacent a backside 507 of IC dies 521. Through vias 924 (e.g., through substrate vias or through silicon vias, TSVs) may have backside connections on or over backside surfaces 907 such that routing from active layer 922 may be provided, as needed. In face-up configuration 931, active layer 922 is opposite substrate 923 with respect to base substrate 501, and active layer 522 may be adjacent IC die 921 or opposite substrate 523 with respect to IC die 921. That is, in the context of multi-level IC stacks, the first layer may be face-up or face-down as may the second layer, which provides four potential stacking configurations: L1 face-down/L2 face-down, L1 face-down/L2 face-up, L1 face-up/L2 face-down, or L1 face-up/L2 face-up. Such permutations increase as the number of levels of the multi-level IC stacks increases.

Returning to FIG. 1, process 100 continues at operation 107, where the IC dies or chiplets are bonded to the base substrate or wafer by evaporating the liquid droplets and optional anneal processing. As discussed, the liquid droplet applied at operation 106 may evaporate quickly and the inorganic materials may hold the IC dies or chiplets in place. A subsequent anneal may then bond the IC dies or chiplets to the bonding regions of the structural wafer by melding metal bond pads and the inorganic materials therebetween.

FIG. 10 is an illustration of a cross-sectional side view of an IC structure 1000 similar to IC structure 900 after liquid droplets 906 evaporate and after bonding to form composite metal structures 1001 and a composite dielectric portion 1002 between each of IC dies 921 and IC dies 521. Furthermore, hydrophobic structures 805, 915 may bond to form composite hydrophobic structures 1003. However, in some contexts, no bonding between hydrophobic structures 805, 915 is evident. The discussed hybrid bonding forms composite metal structures 1001 and composite dielectric portion 1002 across a bonding plane 1043. Thereby, a hybrid bond 1021 between IC dies 921 and IC dies 521 is formed. Each hybrid bond 1021 includes composite metal structures 1001 interspersed in composite dielectric portion 1002, and each hybrid bond 1021 is surrounded by composite hydrophobic structures 1003 or by the pertinent hydrophobic structures deployed in forming hybrid bond 1021. Each of composite metal structures 1001 and composite hydrophobic structures 1003 may have any characteristics discussed with respect to inserts 612, 622 (refer to FIG. 6).

As discussed, each hybrid bond 1021 is surrounded (entirely or mostly) by hydrophobic structures 1003. For example, hydrophobic structure 1003 may extends around a perimeter of hybrid bond 1021, and an outer perimeter of hydrophobic structure 1003 may be fully within an outer perimeter of IC die 921 (refer to FIG. 6). Hydrophobic structure 1003 may extend around a perimeter P1 of hybrid bond 1021, and an outer perimeter P2 of hydrophobic structure 603 may be fully within an outer perimeter P3 of IC die 921. It is noted that a single continuous hydrophobic structure 1003 may surround hybrid bond 1021 or multiple discontinuous hydrophobic structures 603 may surround hybrid bond 1021.

Returning to FIG. 1, as shown with respect to process loop 112, the discussed gap fill, hybrid bond region preparation, self-assembly, and chiplet bonding may be cycled through any number of times to form multi-level 3D die stacks having any number of IC die or chiplet levels over the base substrate wafer such as three-level 3D die stacks, four-level 3D die stacks, or more.

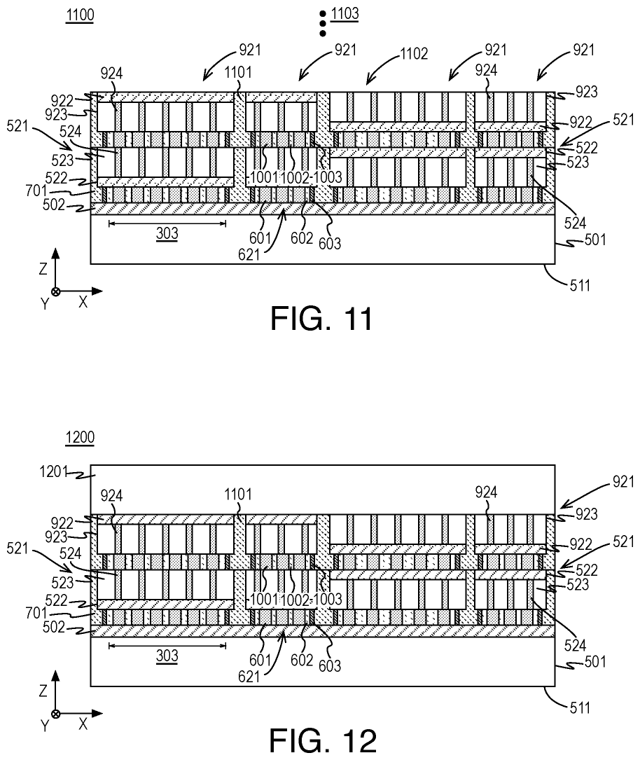

FIG. 11 is an illustration of a cross-sectional side view of IC structure 1100 similar to IC structure 1000 after forming inorganic dielectric 1101 and a substantially planar surface 1102. Inorganic dielectric 1101 may be deposited as a fill material using vapor deposition, for example, and the fill may be planarized to form planar surface 1102. Inorganic dielectric 1101 may be any material suitable dielectric material discussed with respect to inorganic dielectric 701. Planar surface 1102 provides a surface for a subsequent level of IC dies or chiplets in a multi-level 3D die stack, as shown with respect to extension process option 1103, where any number of additional levels of IC dies may be deployed.

Returning to FIG. 1, once process loop 112, if used, is completed, process 100 continues at operation 108, where a final gap fill dielectric is formed between the final level of IC dies and the gap fill dielectric is planarized to provide a top surface for mounting of a support substrate. In some embodiments, the gap fill dielectric is an inorganic dielectric material such as silicon nitride, silicon oxynitride, silicon carbonitride, or silicon carbide. The gap fill dielectric may be formed using any suitable technique or techniques such as deposition techniques followed by planarization. With reference to FIG. 11, inorganic dielectric 1101 may be a final gap fill dielectric and surface 1102 may provide a surface for mounting a support substrate. Although illustrated with two levels of IC dies, IC structure 1100 may include any number of IC die levels in the 3D die stack.

Returning to FIG. 1, process 100 continues at operation 109, where the multi-level die stack may be attached to a structural substrate such as a structural wafer. In some embodiments, the multi-level die stack is bonded to the structural substrate in a wafer-to-wafer bond using an adhesive, an adhesive tape, a dielectric bond, or the like. The structural substrate may be a structural wafer or panel or the like that is absent any active or passive electrical features. For example, the structural substrate may be a monolithic material, a crystalline material, or a composite material. In some embodiments, the structural substrate is monocrystalline silicon such as a silicon wafer. In some embodiments, the structural substrate is or includes germanium, silicon germanium, silicon carbide, or sapphire.

FIG. 12 is an illustration of a cross-sectional side view of IC structure 1200 similar to IC structure 1100 after bonding IC structure 1100 to a structural substrate 1201. Structural substrate 1201 may be bonded to IC structure 1100 using an adhesive, an adhesive tape, or the like (not shown). Structural substrate 1201 may be a structural wafer or panel and is absent any active or passive electrical features. In some embodiments, structural substrate 1201 is or includes monocrystalline, germanium, silicon germanium, silicon carbide, or sapphire. In some embodiments, structural substrate 1201 provides structural support during further processing (e.g., dicing, packaging, assembly, etc.). For example, base substrate 501 may be thinned while IC structure 1100 is mounted to structural substrate 1201. After such processing and during deployment in an electronic device, structural substrate 1201 may provide a heat conduction path while continuing to provide structural support.

As discussed, a multi-level stack of IC dies or 3D die complex may include any number of die levels. In some embodiments, a die is attached that has pre-formed hybrid bonding regions and containment features on only one side of the die (see FIGS. 5 and 9). After attachment using the hybrid bonding regions and containment features, a fill dielectric is deposited and planarized (see FIGS. 7 and 11). Then, hybrid bonding regions are fabricated with the attached dies in place (see FIG. 8), which is then followed by attachment of a next level of IC dies. In other embodiments, the IC dies being attached may have pre-formed hybrid bonding regions and containment features on both sides of the dies.

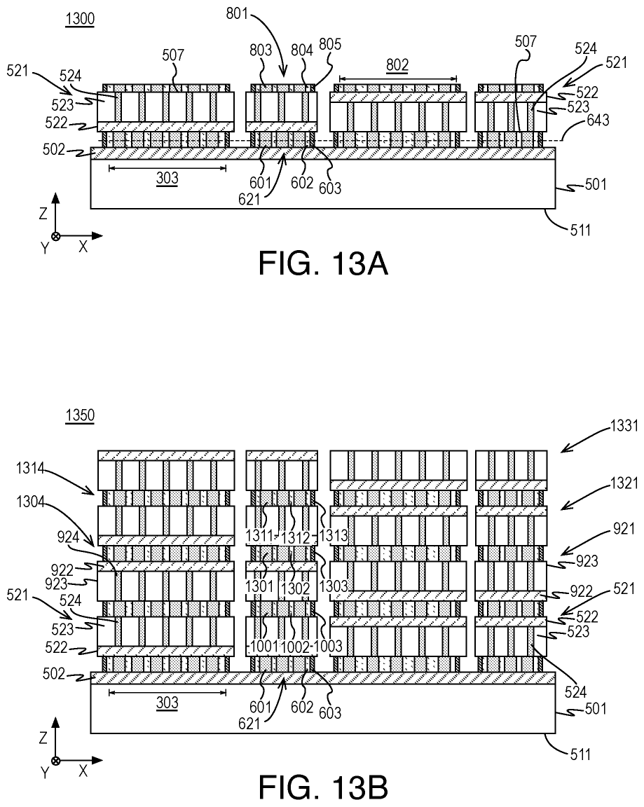

FIG. 13A is an illustration of a cross-sectional side view of an IC structure 1300 similar to IC structure 600 (see FIG. 6) with IC dies 521 having pre-formed hydrophilic structures 801 surrounded by pre-formed hydrophobic structures 805. For example, IC dies 521 may have hydrophilic structures 517 and hydrophobic structures 515 formed on a first side thereof as discussed with respect to FIGS. 2, 3, and 4A-4F, and hydrophilic structures 801 and hydrophobic structures 805 formed on a second side thereof using the same or similar techniques. During hybrid bonding, the first side is attached to base substrate 501 (see FIGS. 5 and 6) while the second side has exposed hydrophilic structures 801 and hydrophobic structures 805 for further bonding.

FIG. 13B is an illustration of a cross-sectional side view of an IC structure 1350 similar to IC structure 1300 after bonding two additional layers of IC dies 1321, 1331. As shown, IC dies 1321 have hydrophilic structures and hydrophobic structures pre-formed on both sides thereof such that hybrid bonding IC dies 1321 forms composite metal structures 1301, composite dielectric portion 1302, and, in some embodiments, composite hydrophobic structures 1303, as discussed herein. In some embodiments, composite metal structures 1301 and composite dielectric portion 1302 are part of a hybrid bond 1304. For example, composite metal structures 1301, composite dielectric portion 1302, and optional composite hydrophobic structures 1303 may having any characteristics discussed with respect to composite metal structures 1001, composite dielectric portion 1002, and, in some embodiments, composite hydrophobic structures 1003.

Furthermore, in the illustrated example, IC dies 1331 have hydrophilic structures and hydrophobic structures pre-formed on only one side (e.g., a bonding side) thereof such that hybrid bonding IC dies 1331 forms composite metal structures 1311, composite dielectric portion 1312, and, in some embodiments, composite hydrophobic structures 1313. In some embodiments, composite metal structures 1311 and composite dielectric portion 1312 are part of a hybrid bond 1314. Composite metal structures 1311, composite dielectric portion 1312, and optional composite hydrophobic structures 1313 may also having any characteristics discussed with respect to composite metal structures 1001, composite dielectric portion 1002, and, in some embodiments, composite hydrophobic structures 1003. It is noted the fabrication steps discussed with respect to FIGS. 13A and 13B eliminate the need for dielectric fill, planarization, and hybrid bonding region/containment feature fabrication after each die attach. For example, dielectric fill and planarization may be performed a single time after all IC dies are attached.

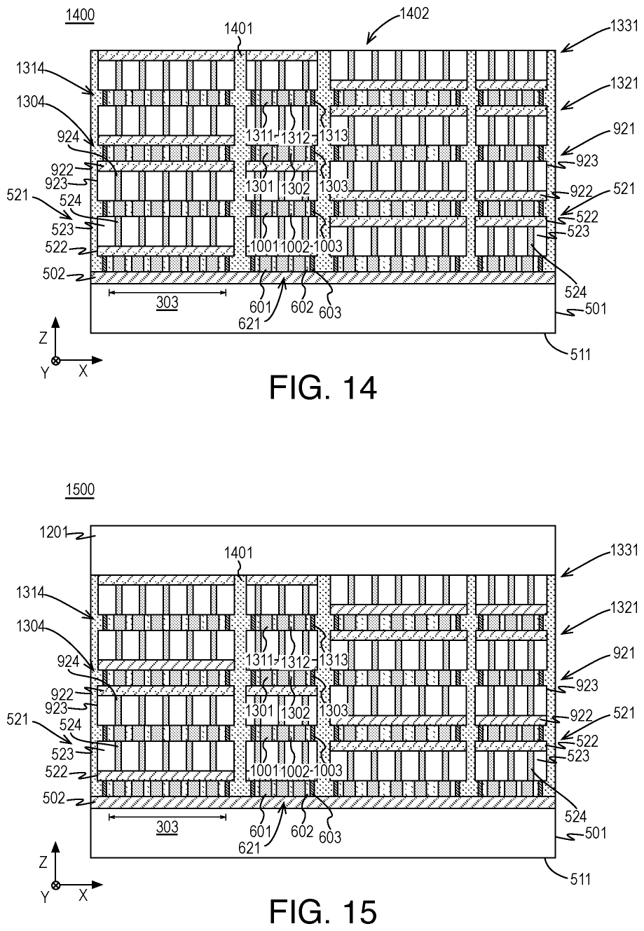

FIG. 14 is an illustration of a cross-sectional side view of IC structure 1400 similar to IC structure 1350 after forming inorganic dielectric 1401 and a substantially planar surface 1402. Inorganic dielectric 1401 may be deposited as a fill material using vapor deposition, for example, and the fill may be planarized to form planar surface 1402. Inorganic dielectric 1401 may be any material suitable dielectric material discussed with respect to inorganic dielectric 701. Planar surface 1102 provides a surface for attachment of a support substrate, for example.

FIG. 15 is an illustration of a cross-sectional side view of IC structure 1500 similar to IC structure 1400 after bonding IC structure 1400 to structural substrate 1201. Structural substrate 1201 may be bonded to IC structure 1100 using an adhesive, an adhesive tape, or the like (not shown) and structural substrate 1201 may be a structural wafer or panel and is absent any active or passive electrical features as discussed above.

In the context of IC structures 1200 and IC structures 1500, IC dies 921, IC dies 1321, and IC dies 1331 are self-aligned and bonded to underlying chiplets or IC dies in previous levels that are of the same size. However, the multi-level self-aligning techniques can be extended to align and bond chiplets or IC dies on a higher level that that are different sizes than the chiplets or IC dies on the lower level. The higher-level IC dies may be entirely within the footprint of a lower-level IC die or higher-level IC dies may have offset edges with respect to lower-level IC dies on each level. This overlapping requires containment features on some levels that are not at the edges of an IC die or are in between the IC dies. Furthermore, an IC die on one level may be aligned and bonded to multiple IC dies on another level and/or to through vias in the dielectric fill in any combination.

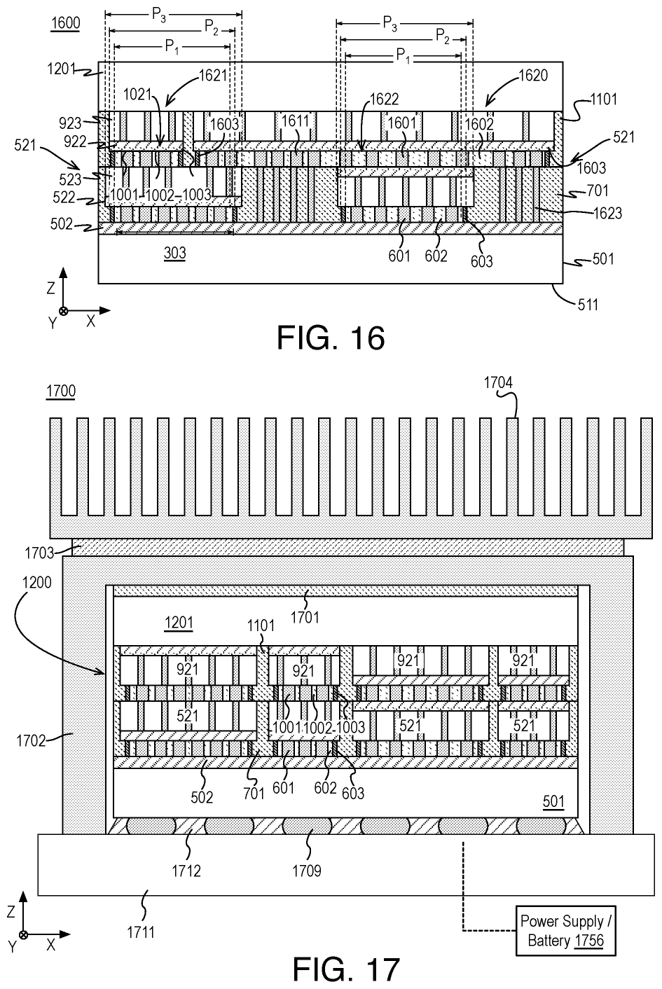

FIG. 16 is an illustration of a cross-sectional side view of IC structure 1600 having a second level of IC dies 1620, 1621 that do not match the size of underlying IC dies 521. As shown, IC die 1621 may be within an outer perimeter P3 of one of IC dies 521. Furthermore, the corresponding hybrid bond 1021 (including composite metal structures 1001 and composite dielectric portion 1002) and hydrophobic structures 1003 are also within outer perimeter P3 of one of IC dies 521.

In contrast, outer edges of IC die 1620 extend beyond an outer perimeter of another of underlying IC dies 521. As shown, a hybrid bond 1622 corresponding to IC die 1620 includes composite metal structures 1601 that are within perimeter P3 of one of IC dies 521 and composite metal structures 1611 that are outside of any perimeter P3 of any of IC dies 521. Similarly, composite dielectric portion 1602 includes portions (or sub-portions) that are within perimeter P3 of one of IC dies 521 and portions (or sub-portions) that are outside of any perimeter P3 of any of IC dies 521. That is, hybrid bond 1622 extends beyond the outside of a single underlying IC die 521. Also as show, hydrophobic structures 1603, which surround hybrid bond 1622 may be partially within a perimeter P3 of an underlying IC die 521 and/or outside of any perimeter of an underlying IC die 521.

Notably, IC structure 1600 includes through vias 1623 (which may be characterized as vias or through assembly vias) that extend from active layer 502, through inorganic dielectric 701, and in contact with one or more of composite metal structures 1611. In some embodiments, as shown, through vias 1623 extend through inorganic dielectric 701 and adjacent IC dies 521 to bypass a single level or layer of IC dies 521. In other embodiments, through vias 1623 may bypass two or more levels or layers of IC dies. Through vias 1623 may be formed using any suitable technique or techniques such as patterning and etch techniques to form holes or openings and metal fill and planarization techniques to form through vias 1623. Through vias 1623 may be any suitable conductive materials such as metal, inclusive of copper. As shown with respect to FIG. 16, the techniques discussed herein provide a flexible, high throughput assembly technique to form IC structures 1600 having a range of architectures.

Returning to FIG. 1, process 100 continues at operation 110, where the integrated circuit structure is segmented (or diced) from the wafer-to-wafer bonded stack. For example, IC structure 1200, IC structure 1500, or any other IC structure discussed herein may be segmented from a wafer using known dicing techniques. Process 100 continues at operation 111, where the resultant device (e.g., IC structure) may be packaged, assembled, and implemented in any suitable form factor device such as a laptop, a netbook, a notebook, an ultrabook, a smartphone, a tablet, a personal digital assistant, an ultra-mobile PC, a mobile phone, a desktop computer, a server, a printer, a scanner, a monitor, a set-top box, an entertainment control unit, a digital camera, a portable music player, a digital video recorder, or the like.

FIG. 17 illustrates an example microelectronic device assembly 1700 including a multi-level 3D die stacks with multiple levels bonded by hybrid bonding regions within containment features, in accordance with some embodiments. As shown, IC structure 1200 may be incorporated into microelectronic device assembly 1700. Although illustrated with respect to the hydrophobic structures of FIG. 4A, IC structure 1200 and, in turn, microelectronic device assembly 1700, may include any hydrophobic structures discussed herein. Furthermore, microelectronic device assembly 1700 may deploy any IC structure discussed herein such as IC structure 1500 or IC structure 1600. Microelectronic device assembly 1700 may include any number of IC structures 1200 mounted to a substrate 1711 via interconnects 1709, which are optionally embedded in a mold or underfill material 1712. Substrate 1711 may be a package substrate, interposer, or board (such as a motherboard). Any number of IC structures 1200 having the same or different hydrophobic structures may be attached to substrate 1711.

Microelectronic device assembly 1700 further includes a power supply 1756 coupled to one or more of substrate 1711 (i.e., a board, package substrate, or interposer), IC dies 521, 921, and/or other components of microelectronic device assembly 1700. Power supply 1756 may include a battery, voltage converter, power supply circuitry, or the like. Microelectronic device assembly 1700 further includes a thermal interface material (TIM) 1701 disposed on a top surface of structural substrate 1201. TIM 1701 may include any suitable thermal interface material and may be characterized as TIM 1. Integrated heat spreader 1702 having a surface on TIM 1701 extends over IC structure 1200 and is mounted to substrate 1711. Microelectronic device assembly 1700 further includes a TIM 1703 disposed on a top surface of integrated heat spreader 1702. TIM 1703 may include any suitable thermal interface material and may be characterized as TIM 2. TIM 1701 and TIM 1703 may be the same materials, or they may be different. A heat sink 1704 (e.g., an exemplary heat dissipation device or thermal solution) is on TIM 1703 and dissipates heat. Microelectronic device assembly 1700 may be used in desktop and server form factors. In other contexts, a heat solution such as a heat pipe or heat spreader may be mounted directly on TIM 1701. Such assemblies may be used in smaller form factor devices. Other heat dissipation devices may be used.

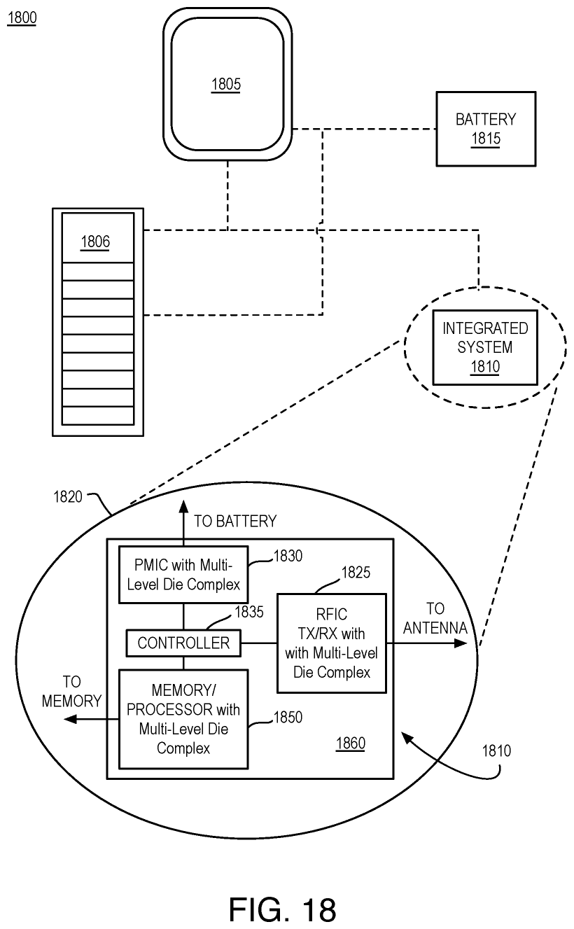

FIG. 18 illustrates exemplary systems 1800 deploying a multi-level 3D die stack with multiple levels bonded by hybrid bonding regions within containment features, in accordance with some embodiments. The system may be a mobile computing platform 1805 and/or a data server machine 1806, for example. Either may employ a component assembly including an IC structure as described herein. Server machine 1806 may be any commercial server, for example, including any number of high-performance computing platforms disposed within a rack and networked together for electronic data processing, which in the exemplary embodiment includes an integrated circuit (IC) die assembly 1850 having a multi-level 3D die stack with multiple levels bonded by hybrid bonding regions within containment features as described elsewhere herein. Mobile computing platform 1805 may be any portable device configured for each of electronic data display, electronic data processing, wireless electronic data transmission, or the like. For example, mobile computing platform 1805 may be any of a tablet, a smart phone, a laptop computer, etc., and may include a display screen (e.g., a capacitive, inductive, resistive, or optical touchscreen), a chip-level or package-level integrated system 1810, and a battery 1815. Although illustrated with respect to mobile computing platform 1805, in other examples, chip-level or package-level integrated system 1810 and a battery 1815 may be implemented in a desktop computing platform, an automotive computing platform, an internet of things platform, or the like. As discussed below, in some examples, the disclosed systems may include a sub-system 1860 such as a system on a chip (SOC) or an integrated system of multiple ICs, which is illustrated with respect to mobile computing platform 1805.

Whether disposed within integrated system 1810 illustrated in expanded view 1820 or as a stand-alone packaged device within data server machine 1806, sub-system 1860 may include memory circuitry and/or processor circuitry 1850 (e.g., RAM, a microprocessor, a multi-core microprocessor, graphics processor, etc.), a power management integrated circuit (PMIC) 1830, a controller 1835, and a radio frequency integrated circuit (RFIC) 1825 (e.g., including a wideband RF transmitter and/or receiver (TX/RX)). As shown, IC dice, such as memory circuitry and/or processor circuitry 1850 may be packaged, assembled, and implemented, such that the package has one or a multi-level 3D die stack with multiple levels bonded by hybrid bonding regions within containment features as described herein. In some embodiments, RFIC 1825 includes a digital baseband and an analog front end module further comprising a power amplifier on a transmit path and a low noise amplifier on a receive path). Functionally, PMIC 1830 may perform battery power regulation, DC-to-DC conversion, etc., and so has an input coupled to battery 1815, and an output providing a current supply to other functional modules. As further illustrated in FIG. 18, in the exemplary embodiment, RFIC 1825 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 1850 may provide memory functionality, high level control, data processing and the like for sub-system 1860. In alternative implementations, each of the SOC modules may be integrated onto separate ICs coupled to a package substrate, interposer, or board.

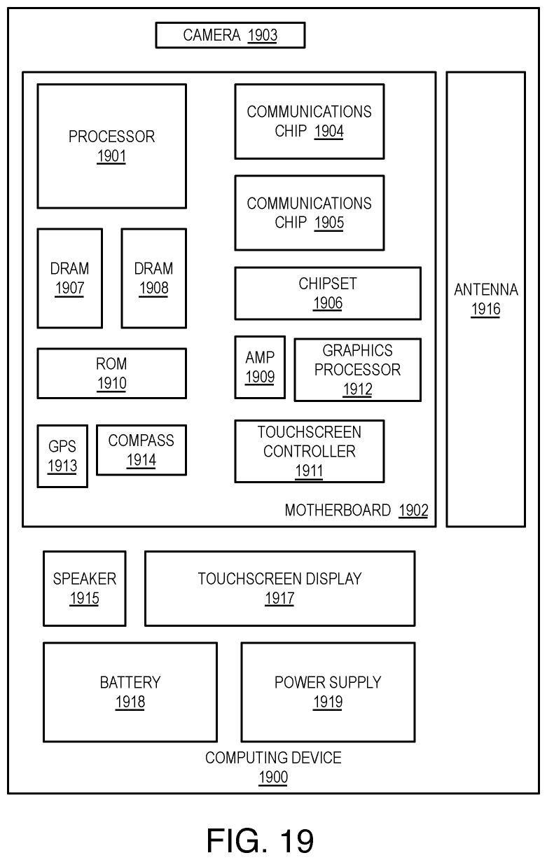

FIG. 19 is a functional block diagram of an electronic computing device 1900, in accordance with some embodiments. For example, device 1900 may, via any suitable component therein, employ a multi-level 3D die stack with multiple levels bonded by hybrid bonding regions within containment features in accordance with any embodiments described elsewhere herein. Device 1900 further includes a motherboard or package substrate 1902 hosting a number of components, such as, but not limited to, a processor 1901 (e.g., an applications processor). Processor 1901 may be physically and/or electrically coupled to package substrate 1902. In some examples, processor 1901 is within a packaged IC assembly that includes a multi-level 3D die stack with multiple levels bonded by hybrid bonding regions within containment features as described elsewhere herein. In general, the term “processor” or “microprocessor” may refer to any device or portion of a device that processes electronic data from registers and/or memory to transform that electronic data into other electronic data that may be further stored in registers and/or memory.

In various examples, one or more communication chips 1904, 1905 may also be physically and/or electrically coupled to the package substrate 1902. In further implementations, communication chips 1904, 1905 may be part of processor 1901. Depending on its applications, computing device 1900 may include other components that may or may not be physically and electrically coupled to package substrate 1902. These other components include, but are not limited to, volatile memory (e.g., DRAM 1907, 1908), non-volatile memory (e.g., ROM 1910), flash memory (e.g., NAND or NOR), magnetic memory (MRAM 1930), a graphics processor 1912, a digital signal processor, a crypto processor, a chipset 1906, an antenna 1916, touchscreen display 1917, touchscreen controller 1911, battery 1918, a power supply 1919, audio codec, video codec, power amplifier 1909, global positioning system (GPS) device 1913, compass 1914, accelerometer, gyroscope, speaker 1915, camera 1903, and mass storage device (such as hard disk drive, solid-state drive (SSD), compact disk (CD), digital versatile disk (DVD), and so forth, or the like.

Communication chips 1904, 1905 may enable wireless communications for the transfer of data to and from the computing device 1900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1904, 1905 may implement any of a number of wireless standards or protocols, including, but not limited to, those described elsewhere herein. As discussed, computing device 1900 may include a plurality of communication chips 1904, 1905. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following pertain to exemplary embodiments.

In one or more first embodiments, an apparatus comprises a first substrate comprising a first interconnect layer, a first integrated circuit (IC) die comprising a second interconnect layer and a backside surface opposite the second interconnect layer, wherein the second interconnect layer or the backside surface of the first IC die is coupled to the first interconnect layer of the first substrate by first composite metal structures therebetween, and wherein the first composite metal structures are surrounded by one or more first hydrophobic structures, and a second IC die coupled to the other of the second interconnect layer or the backside surface of the first IC die by second composite metal structures therebetween, wherein the second composite metal structures are surrounded by one or more second hydrophobic structures.

In one or more second embodiments, further to the first embodiments, the first composite metal structures are interspersed in a first inorganic dielectric material and the second composite metal structures are interspersed in a second inorganic dielectric material.

In one or more third embodiments, further to the first or second embodiments, an outer perimeter of the second inorganic dielectric material is surrounded by the one or more second hydrophobic structures, and wherein an outer perimeter of the second hydrophobic structures is fully within an outer perimeter of the second IC die.

In one or more fourth embodiments, further to the first through third embodiments, the apparatus further comprises a third IC die comprising a third interconnect layer and a backside surface opposite the third interconnect layer, wherein the third interconnect layer of the third IC die is coupled to the first interconnect layer of the first substrate by third composite metal structures therebetween, wherein the third composite metal structures are surrounded by one or more third hydrophobic structures, and wherein the backside surface of the first IC die is coupled to the first interconnect layer of the first substrate by the first composite metal structures.

In one or more fifth embodiments, further to the first through fourth embodiments, the apparatus further comprises a third IC die coupled to the second IC die by third composite metal structures therebetween, wherein the third composite metal structures are surrounded by one or more third hydrophobic structures.

In one or more sixth embodiments, further to the first through fifth embodiments, the apparatus further comprises a dielectric material laterally adjacent to the first IC die, and a via contacting the first interconnect layer of the first substrate and contacting a third composite metal structure laterally adjacent the second composite metal structures and outside a perimeter of the first IC.

In one or more seventh embodiments, further to the first through sixth embodiments, the apparatus further comprises a third IC die coupled to the first interconnect layer of the first substrate by third composite metal structures therebetween, wherein the third composite metal structures are surrounded by one or more third hydrophobic structures, wherein the second IC die is couped to the third IC die by fourth composite metal structures therebetween, and wherein the fourth composite metal structures are surrounded by one or more second hydrophobic structures.

In one or more eighth embodiments, further to the first through seventh embodiments, the apparatus further comprises a second substrate over the second IC die, wherein the second substrate comprises a monolithic material.

In one or more ninth embodiments, further to the first through eighth embodiments, the first or second hydrophobic structures comprise a hydrophobic material, the hydrophobic material comprising one of a self-assembled monolayer material or a polymer film.

In one or more tenth embodiments, further to the first through ninth embodiments, the first or second hydrophobic structures comprise a roughened surface of an inorganic layer or a trench in the inorganic layer.

In one or more eleventh embodiments, further to the first through tenth embodiments, the apparatus or a system further comprises a power supply coupled to the first substrate, the first IC die, or the second IC die.

In one or more twelfth embodiments, a first substrate comprising a first interconnect layer, a first integrated circuit (IC) die comprising a second interconnect layer and a backside surface opposite the second interconnect layer, wherein the second interconnect layer or the backside surface of the first IC die is coupled to the first interconnect layer of the first substrate by first composite metal structures therebetween, wherein the first composite metal structures are surrounded by one or more first structures, and wherein the one or more first structures comprise a first layer of material having an atomic composition of at least ten percent carbon or at least ten percent fluorine, a second IC die coupled to the other of the second interconnect layer or the backside surface of the first IC die by second composite metal structures therebetween, wherein the second composite metal structures are surrounded by one or more second structures, wherein the one or more second structures comprise a second layer of material having an atomic composition of at least ten percent carbon or at least ten percent fluorine.

In one or more thirteenth embodiments, further to the twelfth embodiments, the apparatus further comprises a third IC die comprising a third interconnect layer and a backside surface opposite the third interconnect layer, wherein the third interconnect layer of the third IC die is coupled to the first interconnect layer of the first substrate by third composite metal structures therebetween, wherein the third composite metal structures are surrounded by one or more third structures, wherein the one or more third structures comprise a third layer of material having an atomic composition of at least ten percent carbon or at least ten percent fluorine, and wherein the backside surface of the first IC die is coupled to the first interconnect layer of the first substrate by the first composite metal structures.

In one or more fourteenth embodiments, further to the twelfth or thirteenth embodiments, the apparatus further comprises a third IC die coupled to the second IC die by third composite metal structures therebetween, wherein the third composite metal structures are surrounded by one or more third structures comprise a third layer of material having an atomic composition of at least ten percent carbon or at least ten percent fluorine.

In one or more fifteenth embodiments, further to the twelfth through fourteenth embodiments, the apparatus further comprises a dielectric material laterally adjacent to the first IC die, and a via contacting the first interconnect layer of the first substrate and contacting a third composite metal structure laterally adjacent the second composite metal structures and outside a perimeter of the first IC die.

In one or more sixteenth embodiments, further to the twelfth through fifteenth embodiments, further to the first through tenth embodiments, the apparatus or a system further comprises a power supply coupled to the first substrate, the first IC die, or the second IC die.

In one or more seventeenth embodiments, a method comprises evaporating a first liquid droplet between a first bonding region of a base substrate, the first bonding region surrounded by first hydrophobic structures, and a second bonding region of a first integrated circuit (IC) die, the second bonding region surrounded by second hydrophobic structures, to bond the first and second bonding regions, forming a third bonding region over the first IC die, forming third hydrophobic structures surrounding the third bonding region, and evaporating a second liquid droplet between the third bonding region and a fourth bonding region of a second IC die, the fourth bonding region surrounded by fourth hydrophobic structures, to bond the third and fourth bonding regions.

In one or more eighteenth embodiments, further to the seventeenth embodiments, forming the third bonding region comprises forming an inorganic dielectric material over the bonded first IC die, and forming and first metal pads within the inorganic dielectric material.

In one or more nineteenth embodiments, further to the seventeenth or eighteenth embodiments, the bond between the first and second bonding regions and the bond between the third and fourth regions comprise comprises a die-to-wafer bonding of the first and second IC dies, the method further comprising dicing a multi-level IC structure from the base substrate.

In one or more twentieth embodiments, further to the seventeenth through nineteenth embodiments, the first hydrophobic structures comprise a hydrophobic material, the hydrophobic material comprising one of a self-assembled monolayer material or a polymer film, or the first hydrophobic structures comprise a roughened surface of an inorganic layer or a trench in the inorganic layer.

It will be recognized that the invention is not limited to the embodiments so described, but can be practiced with modification and alteration without departing from the scope of the appended claims. For example, the above embodiments may include specific combination of features. However, the above embodiments are not limited in this regard and, in various implementations, the above embodiments may include undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
a first substrate comprising a first interconnect layer;
a first integrated circuit (IC) die comprising a second interconnect layer and a backside surface opposite the second interconnect layer, wherein the second interconnect layer or the backside surface of the first IC die is coupled to the first interconnect layer of the first substrate by first composite metal structures therebetween, and wherein the first composite metal structures are surrounded by one or more first hydrophobic structures; and
a second IC die coupled to the other of the second interconnect layer or the backside surface of the first IC die by second composite metal structures therebetween, wherein the second composite metal structures are surrounded by one or more second hydrophobic structures.

2. The apparatus of claim 1, wherein the first composite metal structures are interspersed in a first inorganic dielectric material and the second composite metal structures are interspersed in a second inorganic dielectric material.

3. The apparatus of claim 2, wherein an outer perimeter of the second inorganic dielectric material is surrounded by the one or more second hydrophobic structures, and wherein an outer perimeter of the second hydrophobic structures is fully within an outer perimeter of the second IC die.

4. The apparatus of claim 1, further comprising:
a third IC die comprising a third interconnect layer and a backside surface opposite the third interconnect layer, wherein the third interconnect layer of the third IC die is coupled to the first interconnect layer of the first substrate by third composite metal structures therebetween, wherein the third composite metal structures are surrounded by one or more third hydrophobic structures, and wherein the backside surface of the first IC die is coupled to the first interconnect layer of the first substrate by the first composite metal structures.

5. The apparatus of claim 1, further comprising:
a third IC die coupled to the second IC die by third composite metal structures therebetween, wherein the third composite metal structures are surrounded by one or more third hydrophobic structures.

6. The apparatus of claim 1, further comprising:
a dielectric material laterally adjacent to the first IC die; and
a via contacting the first interconnect layer of the first substrate and contacting a third composite metal structure laterally adjacent the second composite metal structures and outside a perimeter of the first IC die.

7. The apparatus of claim 1, further comprising:
a third IC die coupled to the first interconnect layer of the first substrate by third composite metal structures therebetween, wherein the third composite metal structures are surrounded by one or more third hydrophobic structures, wherein the second IC die is couped to the third IC die by fourth composite metal structures therebetween, and wherein the fourth composite metal structures are surrounded by one or more second hydrophobic structures.

8. The apparatus of claim 1, further comprising:
a second substrate over the second IC die, wherein the second substrate comprises a monolithic material.

9. The apparatus of claim 1, wherein the first or second hydrophobic structures comprise a hydrophobic material, the hydrophobic material comprising one of a self-assembled monolayer material or a polymer film.

10. The apparatus of claim 1, wherein the first or second hydrophobic structures comprise a roughened surface of an inorganic layer or a trench in the inorganic layer.

11. The apparatus of claim 1, further comprising a power supply coupled to the first substrate, the first IC die, or the second IC die.

12. An apparatus, comprising:
a first substrate comprising a first interconnect layer;
a first integrated circuit (IC) die comprising a second interconnect layer and a backside surface opposite the second interconnect layer, wherein the second interconnect layer or the backside surface of the first IC die is coupled to the first interconnect layer of the first substrate by first composite metal structures therebetween, wherein the first composite metal structures are surrounded by one or more first structures, and wherein the one or more first structures comprise a first layer of material having an atomic composition of at least ten percent carbon or at least ten percent fluorine; and
a second IC die coupled to the other of the second interconnect layer or the backside surface of the first IC die by second composite metal structures therebetween, wherein the second composite metal structures are surrounded by one or more second structures, wherein the one or more second structures comprise a second layer of material having an atomic composition of at least ten percent carbon or at least ten percent fluorine.

13. The apparatus of claim 12, further comprising:
a third IC die comprising a third interconnect layer and a backside surface opposite the third interconnect layer, wherein the third interconnect layer of the third IC die is coupled to the first interconnect layer of the first substrate by third composite metal structures therebetween, wherein the third composite metal structures are surrounded by one or more third structures, wherein the one or more third structures comprise a third layer of material having an atomic composition of at least ten percent carbon or at least ten percent fluorine, and wherein the backside surface of the first IC die is coupled to the first interconnect layer of the first substrate by the first composite metal structures.

14. The apparatus of claim 12, further comprising:
a third IC die coupled to the second IC die by third composite metal structures therebetween, wherein the third composite metal structures are surrounded by one or more third structures comprise a third layer of material having an atomic composition of at least ten percent carbon or at least ten percent fluorine.

15. The apparatus of claim 12, further comprising:
a dielectric material laterally adjacent to the first IC die; and
a via contacting the first interconnect layer of the first substrate and contacting a third composite metal structure laterally adjacent the second composite metal structures and outside a perimeter of the first IC die.

16. The apparatus of claim 15, further comprising a power supply coupled to the first substrate, the first IC die, or the second IC die.

17. A method, comprising:
evaporating a first liquid droplet between a first bonding region of a base substrate, the first bonding region surrounded by first hydrophobic structures, and a second bonding region of a first integrated circuit (IC) die, the second bonding region surrounded by second hydrophobic structures, to bond the first and second bonding regions;
forming a third bonding region over the first IC die;
forming third hydrophobic structures surrounding the third bonding region; and
evaporating a second liquid droplet between the third bonding region and a fourth bonding region of a second IC die, the fourth bonding region surrounded by fourth hydrophobic structures, to bond the third and fourth bonding regions.

18. The method of claim 17, wherein forming the third bonding region comprises forming an inorganic dielectric material over the bonded first IC die, and forming and first metal pads within the inorganic dielectric material.

19. The method of claim 17, wherein the bond between the first and second bonding regions and the bond between the third and fourth regions comprise comprises a die-to-wafer bonding of the first and second IC dies, the method further comprising dicing a multi-level IC structure from the base substrate.

20. The method of claim 17, wherein the first hydrophobic structures comprise a hydrophobic material, the hydrophobic material comprising one of a self-assembled monolayer material or a polymer film, or the first hydrophobic structures comprise a roughened surface of an inorganic layer or a trench in the inorganic layer.
